(19) United States
(12) Patent Application Publication
(10) Pub. No.: US 2014/0120393 A1
(43) Pub. Date: May 1, 2014

(54) PRINTED CIRCUIT FOR INTERCONNECTING AND MEASURING BATTERY CELLS IN A BATTERY

(71) Applicant: COMMISSARIAT À L'ÉNERGIE ATOMIQUE ET AUX ÉNERGIES ALTERNATIVES, Paris (FR)

(72) Inventors: Matthieu Desbois-Renaudin, Villard De Lans (FR); Lionel De Paoli, Odenas (FR)

(21) Appl. No.: 14/126,605

(22) PCT Filed: Jan. 31, 2012
(86) PCT No.: PCT/EP2012/051595

§ 371 Date: Dec. 16, 2013

(30) Foreign Application Priority Data
Jun. 17, 2011 (FR) 1155350

(51) Int. Cl. H01M 10/48; H05K 1/18

(52) U.S. Cl. CPC H01M 10/482; H05K 1/181
USPC 429/92; 361/748

(57) ABSTRACT

A printed-circuit board to be fixed to a battery of accumulators includes a substrate comprising conductive tracks, a circuit for measuring voltage connected to the conductive tracks, and an electric interconnection element formed by a single piece, which is conductive and flexible, the interconnection element having a thickness of 0.3 mm to 1.5 mm. The interconnection element comprises a single portion fixed to the substrate by several force-fittings and electrically connected to one of the conductive tracks, and at least two portions overhanging the fixed portion and mobile relative to the substrate. The overhanging portions are formed at ends of a conductive strip disposed to be overhang the fixed portion. The conductive strip connects to the fixed portion by a junction that is narrower than the conductive strip.

### RELATED APPLICATIONS

This application is the national stage under 35 USC 371 of PCT/EP2012/051595, filed on Jan. 31, 2012, which claims the benefit of the priority date of French application FR 1155350, filed on Jun. 17, 2011, the contents of which are herein incorporated by reference.

### FIELD OF INVENTION

The invention pertains to batteries of electrochemical accumulators. These batteries can be used, for example, in the field of electric and hybrid transportation or that of embedded systems.

### BACKGROUND

An electrochemical accumulator usually has a nominal voltage having one of the following orders of magnitude:

1.2 V for NiMH type batteries,

3.3 V for lithium-ion iron phosphate or LiFePO4, technology,

4.2 V for cobalt-oxide-based lithium ion type technology.

These nominal voltages are too low for the requirements of most systems to be powered. To obtain the appropriate level of voltage, several accumulators are placed in series. To obtain high values of power and capacitance, several groups of accumulators are placed in parallel. The number of stages (number of accumulators in series) and the number of accumulators in parallel in each stage vary according to the voltage, the current and the capacitance desired for the battery. The association of several accumulators is called a “battery of accumulators.”

When designing a battery of accumulators, it is sought to obtain a certain level of power at a defined operating voltage. To maximize the power, the current delivered is maximized by reducing the internal parasitic resistance of the battery to the utmost possible extent.

Lithium-ion type batteries are well suited to transportation applications because of their capacity to store substantial energy in a small mass. Among lithium-ion battery technologies, iron-phosphate-based batteries offer a high level of intrinsic security as compared with cobalt-oxide-based lithium-ion batteries. However, such batteries have the disadvantage of slightly lower energy per unit mass. Besides, lithium-ion batteries also have a minimum voltage below which an accumulator can suffer deterioration.

In practice, for high-power applications, it is necessary to specifically design a battery having an output voltage, capacity and power adapted to this application. The designing implies especially the choice of the type of accumulator, the choice of a number of series-connected accumulator stages, and the choice of a number of parallel-connected arms.

The manufactured battery must meet a certain number of constraints especially of mechanical resistance, security against heating, the appearance of short circuits or the presence of foreign bodies, electrical losses limited to the utmost possible extent, and a space requirement and a cost price limited to the utmost possible extent. A control circuit must also ensure that the voltage of the accumulators is maintained between the minimum and the maximum operating voltages.

One existing solution involves screwing in conductive bars forming an electrical power connection in the form of a bus. These bars are screwed onto the accumulators. A measurement of the voltage is made by a pin tightened at the same point as the point at which a conductive bar is screwed. These solutions have several drawbacks. For example, the loose wires in a battery pack are a major source of shorting risks. In addition, positioning these wires is a tedious and non-automated task.

Another solution involves the use of a printed-circuit board of small thickness to which a copper plate with a thickness of about 1 mm is bonded. This plate is then machined so as to electrically separate the zones that will serve as power connections between the electrochemical accumulators. The voltage information is sent back on the tracks of the printed-circuit board by means of conductive rivets (made of copper and the like). This approach appreciably improves security but does not allow for the addition of surface-mounted components on the printed-circuit boards given the flexibility of these circuits. It is indeed the printed-circuit board that absorbs the differences in height between the terminals of the different electrochemical accumulators.

Another solution is described in the US patent document US2008/0254356. This document describes an interconnection structure between accumulators of a battery and a connection structure to a circuit for monitoring the charging of the battery. The battery is included in a hand-held tool and the supervision of the charging of the accumulators is of prime importance in ensuring its service life.

An interconnection structure is formed by a metal sheet ensuring the electrical series connections between the accumulators as well as an electrical connection with a circuit for measuring voltage in a printed-circuit board substrate. The metal sheet is folded at right angles to demarcate, firstly, two lugs for fastening to the substrate and, secondly, a plate that is soldered on the terminals of the accumulators. Each fastening lug is crossed by a rivet. Using a sufficiently thin metal sheet makes it possible to deform this sheet at the junction between the fastening lugs and the plate so as to enable compensation for the variations between the accumulators or the thermal expansion of these accumulators. Conduction through the plate and the fastening lugs furthermore enables the measuring circuit to recover the voltage at a terminal of an accumulator soldered to the plate. The thinness of the metal sheet also enables absorption of the vibrations induced by the portable tool (typically a drill) and thus to protect the printed-circuit board. The thinness of the metal sheet furthermore makes it possible to assemble the plate and the terminals of the accumulators by soldering.

In practice, such an interconnection structure enables only a fairly limited play for the accumulators. In addition, such an interconnection structure is not appropriate for the conduction of high currents and therefore proves to be unsuitable for power batteries. Furthermore, to ensure satisfactory fastening of the interconnection structure to the substrate of the printed-circuit board, this fastening takes up substantial space on the substrate. Furthermore, the fastening operation requires great precision and dictates certain conditions of sizing.

### SUMMARY

The invention seeks to resolve one or more of these drawbacks. The invention thus pertains to a printed-circuit board to be fixed to a battery of accumulators comprising:
a substrate comprising conductive tracks;
a circuit for measuring voltage connected to the conductive tracks;
an electric interconnection element formed by a single piece, that is conductive and flexible, the interconnection element having a thickness of 0.3 mm to 1.5 mm, the interconnection element comprising:
   a single portion fixed to said substrate, fixed to the substrate by several force fittings and electrically connected to one of said conductive tracks;
   at least two portions overhanging the fixed portion and mobile relative to the substrate, said two overhanging portions being formed at the ends of a conductive strip, disposed so as to be overhanging the fixed portion, said conductive strip being connected to the fixed portion by means of a junction, the width of which is smaller than the width of the conductive strip.

According to one variant, the distance between the fixed portion and the distal point of the overhanging portions is greater than 35 mm.

According to one variant, the substrate comprises via holes and the overhanging portions are disposed so as to be plumb with the respective via holes.

According to another variant, the overhanging portions comprise via holes localized so as to be plumb with the respective via holes of the substrate.

According to yet another variant, said substrate has a thickness greater than 1.5 mm.

According to one variant, the printed-circuit board furthermore comprises surface-mounted electronic components connected to at least one of said conductive tracks.

According to another variant, the interconnection element is made out of a material chosen from the group comprising aluminum alloys and copper alloys.

The invention also relates to a battery comprising:
a printed-circuit board as described here above;
a support to which the printed-circuit board is fixed;
at least two electrochemical accumulators housed in said support and each comprising a terminal connected to a respective overhanging portion of the interconnection element of the printed-circuit board.

According to one variant, said electrochemical accumulators each comprise two connection terminals disposed at a same end of the accumulator.

According to another variant, the battery comprises a compressible material interposed between the support and the end of an accumulator opposite the end comprising said connection terminals.

According to another variant, the battery comprises a printed-circuit board and screws passing through the holes of the overhanging portions and fixedly attaching the overhanging portions to a respective terminal of said accumulators.

According to yet another variant, the printed-circuit board comprises a circuit for balancing the charging of said accumulators connected to said conductive tracks.

According to one variant, the printed-circuit board comprises:
two power output terminals of the battery;
two other conductive interconnection elements electrically connected to a respective power output terminal, attached to the substrate and connecting each of the terminals of several electrochemical accumulators.

### DESCRIPTION OF THE DRAWINGS

Other features and advantages of the invention shall appear more clearly from the following description given here below by way of an indication that is in no way exhaustive, with reference to the appended drawings, of which:

FIG. 1 is a view in section of a side of a battery according to one embodiment of the invention;

FIG. 2 is a bottom view of a printed-circuit board of the battery of FIG. 1;

FIG. 3 is a top view of a printed-circuit board of the battery of FIG. 1;

FIG. 4 is a side view in section of details of an interconnection element undergoing deformation;

FIG. 5 is a bottom view of the interconnection element of FIG. 4;

FIG. 6 is a top view of the interconnection element of FIG. 4; and

FIG. 7 is a side view in section of the details of a variant of an interconnection element undergoing deformation.

### DETAILED DESCRIPTION

The invention proposes a printed-circuit board that is to be attached to a battery, especially a power battery (presenting typically voltage of over 24V and a capacitance of over 10 Ah). The printed-circuit board comprises a substrate provided with conductive tracks connected to a circuit for measuring voltage (and advantageously a circuit for balancing charges). The printed-circuit board furthermore comprises an electrical power connection element formed as a single piece that is conductive and flexible. To favor both electrical conduction and flexibility, the interconnection element advantageously has a thickness of 0.3 mm to 1.5 mm. This interconnection element comprises a single portion attached to the substrate and connected to one of the conductive tracks. This single fixed portion is fixed to the substrate by several force-fittings. The interconnection element also comprise two overhanging portions overhanging the fixed portion, these overhanging portions being formed at the ends of a conductive strip disposed so as to be overhanging the fixed portion. The conductive strip is connected to the fixed portion by means of a junction whose width is smaller than the width of the conductive strip. These overhanging portions are mobile relative to the substrate.

The overhanging portions provide for a power connection between two terminals belonging to two accumulators of the battery. Owing to the sizing of the interconnection element, a power current in series can pass through the strip of the interconnection element. This power current could, for example, have a nominal amplitude of 30 to 500 A. Owing to the flexibility of the interconnection element, the overhanging portions can shift relative to the substrate by the bending of the strip and/or by the twisting of its junction at the fixed portion. The use of a single fixed portion and a junction of reduced width favors such twisting. The presence of several force-fittings provides for the electrical connection between the terminals of the accumulators and the conductive tracks. This is obtained on a limited surface area and, at the same time, in preventing a pivoting of the interconnection element about an axis normal to the substrate. The fixed portion provides firstly for mechanical worthiness of the interconnection element on the substrate and secondly for electrical connection between the terminals of two accumulators and the measuring circuit.

Thus, the printed-circuit board can be fixed directly to the battery by providing for a power connection between accumulators as well as a connection to the measuring circuit without any excessive deformation of the printed-circuit board and its electronic components because of manufacturing variations between the different accumulators, distinct thermal expansion values between these accumulators or any other mechanical stress, such as vibrations, impacts, acceleration in all three directions, etc.

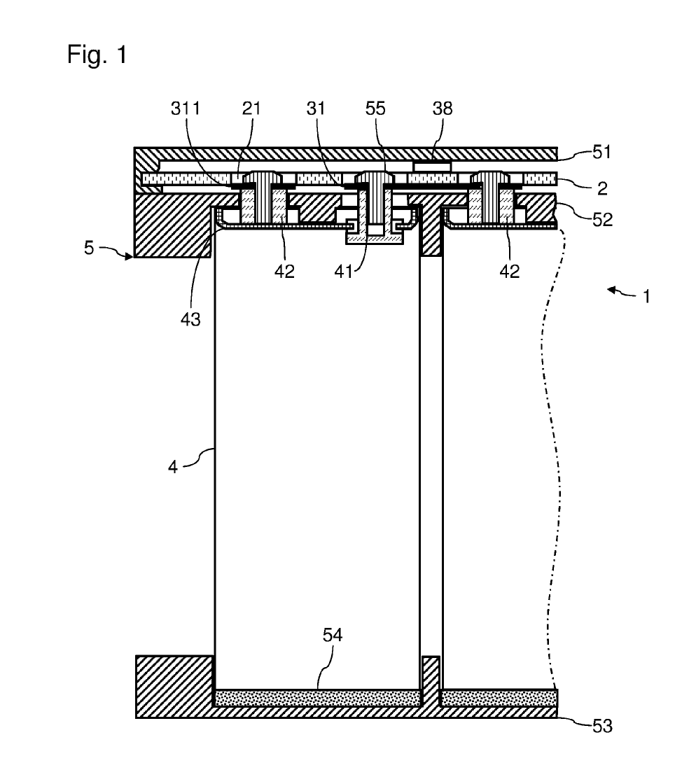

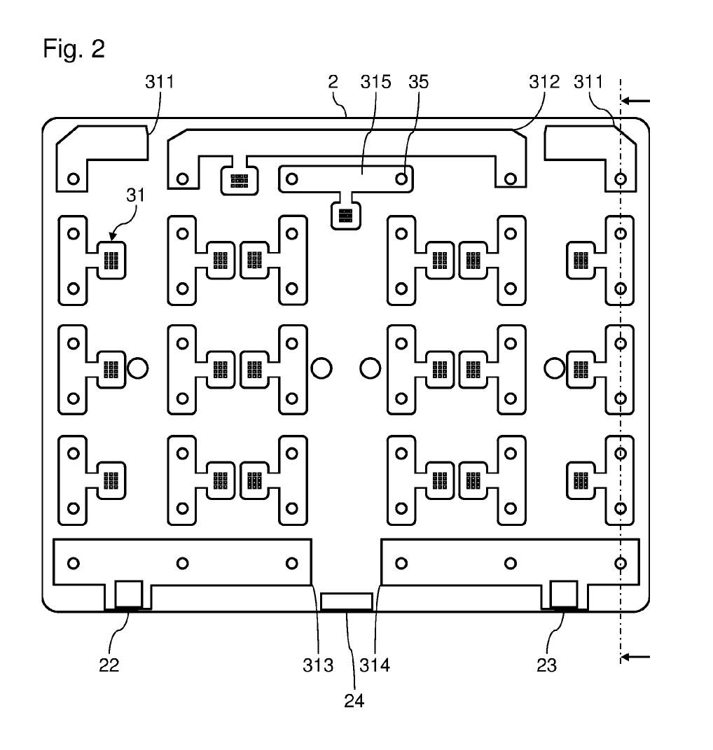

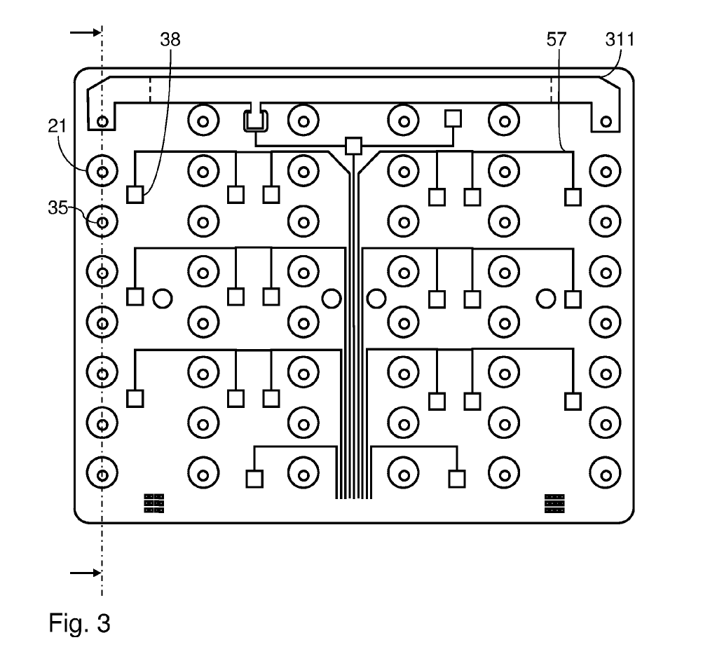

FIG. 1 is a side view in partial section of a battery 1 according to one embodiment of the invention. The battery 1 has a printed-circuit board 2 illustrated in greater detail in a bottom view and in a top view respectively in FIG. 2 and FIG. 3.

The battery 1 comprises a support 5. The support 5 is intended to house a plurality of accumulators 4 of the battery and intended to receive the printed-circuit board 2. The support 5 advantageously comprises a lower flange 53 and an upper flange 52. The accumulators 4 are held between the flanges 52 and 53.

First axial ends of the accumulators 4 are placed in respective housings of the upper flange and second axial ends of the accumulators 4 are placed in respective housings of the lower flask. The accumulators 4 extend thus axially between the flanges 52 and 53. The housings of the flanges 52 and 53 are advantageously configured to clamp the axial and transversal motions of the accumulators 4. The accumulators 4, thus held along the different axes by the flanges 52 and 53, are advantageously separated by an air gap. Attached shafts (not shown) fixedly join the flanges 52 and 53. The attached shafts extend along the axis of the accumulators 4 and enable the exertion of a holding force between the flanges 52 and 53.

In the illustrated example, the accumulators 4 comprise connection terminals 41 and 42 disposed at a same axial end. Such accumulators 4 enable an interconnection to be made easily. The terminals 41 and 42 are fixed in a manner known per se to a flange 43 at one end of the accumulator 4. The terminals 41 and 42 pass through holes (not referenced) made in the upper flange 52. A lining of compressible material 54, for example foam, is advantageously disposed between one end of the accumulators 4 and one of the flanges. The compressible material can be configured to enable a deformation of about 1 mm by the tightening of the shafts fixedly joining the flanges 52 and 53. In the illustrated example, the lining 54 is positioned in the bottoms of the housings of the lower flange 53 at the end of the accumulator 4 opposite the terminals 41 and 42. The lining 54 compensates for variations in the axial dimension of the different accumulators 4 and the thermal expansion of these accumulators 4.

The support 5 furthermore comprises a holding element 51 advantageously fixed to the upper flange 52. The printed-circuit board 2 is fixed to this holding element 51. The printed-circuit board 2 comprises a substrate. The interconnection elements 31 and 311 are fixed to this substrate. The terminals 41 and 42 of the accumulators 4 are electrically connected to these interconnection elements. The terminals 41 and 42 are fixed to the interconnection elements by means of screws 55. The terminals 41 and 42 can also be fixed to the interconnection elements by any other fastening means such as soldering, riveting or mechanical crimping. The screws 55 pass through the via holes 21 made in the substrate.

The printed-circuit board 2 illustrated in FIGS. 2 and 3 is configured for the series-connection of eight stages of three parallel-connected accumulators 4. The printed-circuit board 2 has a positive power output terminal 22 and a negative power output terminal 23. The terminal 22 is connected to an interconnection element 313 that is to be connected to the positive terminals of three accumulators. The terminal 23 is connected to an interconnection element 314 that is to be connected to the negative terminals of three accumulators. The interconnection elements 313 and 314 are disposed at a same edge of the printed-circuit board 2. The printed-circuit board 2 furthermore comprises a plurality of interconnection elements 31, each designed to connect two accumulators 4 in series. The printed-circuit board 2 furthermore comprises an interconnection element 311, an interconnection element 312 and an interconnection element 315.

The interconnection elements are conductive and flexible. The interconnection element 311 has a part extending on the upper face of the substrate and mobile portions extending on the lower face of the substrate. The broken lines illustrate the junction between the mobile portions and the upper part of the interconnection element 311. Corresponding holes are made in the substrate. The interconnection elements 31, 312, 313, 314 and 315 comprise a fixed portion 33 fixed to the substrate of the circuit on its lower face. This fixed portion 33 makes it possible both to fix these interconnection elements to the substrate and to provide their electrical connection with conductive tracks 57 made on the upper face of the substrate. The interconnection elements 31, 312, 313, 314 and 315 also comprise two portions overhanging the fixed portion 33. The overhanging portions in this case are formed by a strip 36 disposed so as to be overhanging the fixed portion 33.

The interconnection element 31 according to the first variant of the invention is illustrated in greater detail in a bottom view and in a top view respectively in FIGS. 5 and 6. The strip 36 is connected to the fixed portion 33 by means of a conductive junction 34. The conductive junction 34 provides for the electrical conduction between the strip 36 and the fixed portion 33. The strip 36 provides the electrical power connection between two of its ends that are to be connected to terminals of accumulators 4. The strip 36 and especially its ends are mobile relative to the substrate. Thus, the ends of the strip 36 can shift along the direction of the axis of the accumulators 4 by the bending of the strip 36 without in any way thereby inducing undue stresses on the substrate. Furthermore, the ends of the strip 36 can shift along the direction of the axis of the accumulators by the twisting of the junction 34. This twisting is favored by the presence of a single portion 33 fixed to the printed-circuit board 2 even when the interconnection element 31 is relatively thick in order to favor the electrical conduction of a power battery. This twisting is also favored by the junction 34 having a width smaller than the width of the strip 36. Thus, optimal electrical conduction is ensured between the ends of the strip 36. At the same time, the bending of the junction 34 is favored even when the interconnection element 31 is relatively thick in order to facilitate the electrical conduction of a power battery. Positioning the ends of the strip 36 so that they overhang the junction 34 makes it possible to tolerate a major shift of the terminals of the accumulators that are fixed thereto, even when the interconnection element 31 is relatively thick, in order to favor the electrical conduction of a power battery. Thus, the interconnection elements can easily adapt to the manufacturing variations of the accumulators 4 or their thermal expansion (which are sometimes distinct owing to potentially non-homogenous cooling). The junction 34 enables an proportionate increase in the amplitude of the shift of the ends of the strip 36 for a given force. Advantageously, the fixed portion 33 has a width greater than that of the junction 34. Thus, the fixed portion 33 ensures a great surface of electrical contact and fastening for the interconnection element with the substrate. Such an interconnection element 31 allows for substantial clearance for the ends of the strip 36 with reduced space requirement.

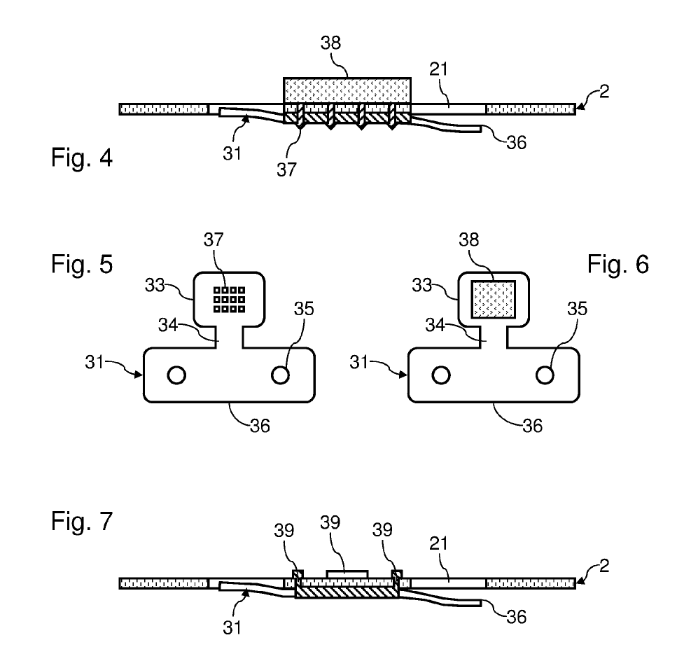

An example of a strip 36 of an interconnection element 31 is bent by the terminals of accumulators 4 in FIG. 4. In this example, one of the ends of the strip 36 is shifted downwards, while the other end of the strip 36 is shifted upwards. The end shifted upwards is shifted inside a hole 21 made in the substrate.

The fastening of the interconnection element 31, 311, 312, 313, 314 and 315 to the substrate of the printed-circuit board 2 is made by several force-fittings. The use of several force-fittings provides for contact at several points with the conductive tracks of the printed-circuit board 2. The use of several force-fittings blocks the rotation of the interconnection element 31 about an axis normal to the printed-circuit board 2.

In the example illustrated in FIG. 4, conductive tracks 37 pass through the substrate of the printed-circuit board 2 to ensure the fastening of the interconnection element to the substrate. The rods 37 advantageously also provide for electrical connection between the fixed part 32 and the conductive tracks 57. To this end, the rods 37 are force-fitted into the substrate of the printed-circuit board 2 and in the fixed part 33. Holes are thus provided in the substrate and in the fixed part 33 in order to deform the rods 37 when they are being force-fitted. The holes of the substrate are advantageously metalized to provide for electrical contact with the conductive tracks of the printed-circuit board. The rods 37 can be fixed in a handling support 38. The combination of the rods 37 and the handling support 38 can be made in the form of press-fit inserts. The use of such press-fitted inserts enables the fastening of the interconnection element to the substrate of the printed-circuit board 2 in a single operation and with reduced space requirement. Inserts such as those commercially available under the reference Press Fit by the firm Wurth Elektronik can especially be used. The unattached end of the rods 37 can be deformed plastically to form beads reinforcing the mechanical link.

The conductive tracks 57 are connected to a circuit 24 for measuring voltage. The circuit 24 can be made with surface-mounted electronic components. Using the conductive tracks 57, the circuit 24 for measuring voltage can measure the voltage at the terminals of each of the accumulators 4. The circuit 24 for measuring voltage can especially be included in a circuit for controlling the charging of the battery 1. This circuit for controlling the charging of the battery 1 can also carry out the charging or discharging of the different stages of accumulators 4 by means of the conductive tracks 57. This control circuit can thus carry out the balancing of the charges of the different stages of the battery 1. The interconnection elements 311, 312 and 315 enable the series-connection of the terminals of accumulators 4 belonging to two opposite sides of the battery 1.

The substrate of the printed-circuit board 2 advantageously has a plurality of via holes 21 disposed so as to be plumb with the mobile portions of the interconnection elements. These via holes 21 enable an increase in the upward mobility of the mobile portions. These holes 21 also enable the fastening of the terminals of the accumulators 4 to interconnection elements. In the example, the mobile portions of the interconnection elements advantageously have via holes 35 designed to provide a passage for the body of the screws 55 fixed into terminals 41 and 42. The via holes 35 are thus disposed so as to be plumb with the via holes 21. It is also possible to envisage the making of the electrical connection and the mechanical connection of the terminals 41 and 42 to the interconnection elements by any other appropriate means, for example by soldering. The holes 21 thus give access to soldering electrodes.

The interconnection elements are formed as a single piece out of a conductive material. Such interconnection elements can especially be made easily by swaging or out of cut-out and folded sheet metal. Such interconnection elements can, for example, be made out of aluminum alloy, phosphor or any copper alloy, materials relatively easy to transform and having valuable properties of electrical conduction and flexibility. In order to be easily deformable, an interconnection element made out of copper will have a thickness of 0.3 to 1.5 mm. To favor the bending of the overhanging portions, the distance between the fixed portion 33 and the distal point of the overhanging portions is advantageously greater than 35 mm.

In order to reduce to the utmost the deformations induced by the accumulators 4 on the printed-circuit board 2, the substrate advantageously has a thickness of over 1.5 mm. The substrate will advantageously have a modulus of elasticity greater than 15000 MPa. The substrate could, for example, be made out of epoxy resin. The substrate could comprise several layers of copper tracks. Such a configuration will provide optimum protection and flexibility to any surface-mounted electronic components on the substrate of the printed-circuit board 2. The interconnection elements and the substrate will advantageously be sized so that the maximum deformation induced on the substrate by the terminals 41 and 42 is at least five times smaller than the maximum deformation of an interconnection element by these terminals 41 or 42.

FIG. 7 illustrates another variant of an interconnection element 31. This variant differs from the variant of FIGS. 4 to 6 solely by the structure of the fixed portion. According to this variant, the interconnection element 37 comprises tabs 39 formed as a single piece in the fixed portion 33. The fixed portion 33 comprises a flat median part. The tabs 39 are, for example, formed by folding of projections of the fixed portion 33 so as to be oriented along the perpendicular to the median part of the fixed portion 33. As illustrated, the tabs 39 pass through the substrate of the printed-circuit board 2. In the example illustrated, the tabs extend from several edges of the median part of the fixed portion 33, thus providing for better blocking in rotation around an axis normal to the substrate of the printed-circuit board 2. In this example, the tabs 39 pass through holes made in the substrate of the printed-circuit board 2. These holes are made so as to deform the tabs 39 when they are being force-fitted into in these holes. The holes of the substrate are advantageously metalized to provide electrical contact with the conductive tracks of the printed-circuit board 2. Such tabs 39 enable the making of numerous electrical and mechanical connections by force-fitting in a single operation and with reduced space requirement. The free end of the tabs 39 can be deformed plastically after force-fitting to form beads reinforcing the mechanical link.

Although the invention has been described in an embodiment with electrochemical accumulators having connection terminals at a same end, those skilled in the art will also be able to make a battery according to the invention by means of accumulators having connection terminals at opposite ends.

1-13. (canceled)

14. An apparatus comprising a printed-circuit board to be fixed to a battery of accumulators, said printed-circuit board comprising a substrate comprising conductive tracks, a circuit for measuring voltage connected to said conductive tracks, and an electric interconnection element formed by a single piece, which is conductive and flexible, said interconnection element having a thickness of 0.3 mm to 1.5 mm, wherein said interconnection element comprises a single portion fixed to said substrate by several force-fittings and electrically connected to one of said conductive tracks, and at least two portions overhanging said fixed portion and mobile relative to said substrate, said two overhanging portions being formed at ends of a conductive strip disposed so as to be overhanging said fixed portion, said conductive strip being connected to said fixed portion by a junction that is narrower than said conductive strip.

15. The apparatus of claim 14, wherein a distance between said fixed portion and a distal point of said overhanging portions is greater than 35 mm.

16. The apparatus of claim 14, wherein said substrate comprises via holes, and wherein said overhanging portions are disposed to be plumb with respective via holes of said substrate.

17. The apparatus of claim 14, wherein said overhanging portions comprise via holes localized so as to be plumb with said respective via holes of said substrate.

18. The apparatus of claim 14, wherein said substrate has a thickness greater than 1.5 mm.

19. The apparatus of claim 14, further comprising surface-mounted electronic components connected to at least one of said conductive tracks.

20. The apparatus of claim 14, wherein said interconnection element comprises an aluminum alloy.

21. The apparatus of claim 14, wherein said interconnection element comprises a copper alloy.

22. The apparatus of claim 14, further comprising a support to which said printed-circuit board is fixed, and at least two electrochemical accumulators housed in said support, each of which comprises a terminal connected to a respective overhanging portion of said interconnection element of said printed-circuit board.

23. The apparatus of claim 22, wherein said electrochemical accumulators each comprise two connection terminals disposed at a common end of said accumulator.

24. The apparatus of claim 23, further comprising a compressible material interposed between said support and an end of an accumulator opposite said end comprising said connection terminals.

25. The apparatus of claim 22, further comprising screws passing through said holes of said overhanging portions and fixedly attaching said overhanging portions to a respective terminal of said electrochemical accumulators.

26. The apparatus of claim 22, wherein said printed-circuit board comprises a circuit for balancing charging of said electrochemical accumulators connected to said conductive tracks.

27. The apparatus of claim 22, wherein said printed-circuit board comprises two power output terminals for receiving current from said electrochemical accumulators, and two other conductive interconnection elements electrically connected to a respective power output terminal attached to said substrate and connecting each of said terminals of several electrochemical accumulators.
